(19) United States
(12) Patent Application Publication
(10) Pub. No.: US 2025/0380795 A1
(43) Pub. Date: Dec. 18, 2025

(54) BRUSH DETACHABLE MODULE, BRUSH REPLACING MODULE INCLUDING THE SAME, AND SUBSTRATE CLEANING APPARATUS INCLUDING THE BRUSH DETACHABLE MODULE

(71) Applicant: Samsung Electronics Co., Ltd., Suwon-si (KR)

(72) Inventors: Sukyung HONG, Suwon-si (KR); Donghoon KWON, Suwon-si (KR)

(73) Assignee: Samsung Electronics Co., Ltd., Suwon-si (KR)

(21) Appl. No.: 19/008,023

(22) Filed: Jan. 2, 2025

(30) Foreign Application Priority Data
Jun. 18, 2024 (KR) 10-2024-0078656

(51) Int. Cl. A46B 5/00; A46B 13/00; B08B 1/12; H01F 7/06

(52) U.S. Cl. CPC A46B 5/0095; B08B 1/12; H01F 7/06; A46B 13/001

(57) ABSTRACT

Disclosed is a brush detachable module, which comprises a detachable portion configured to detach a brush for cleaning a substrate, a moving portion configured to move the detachable portion in an up-and-down direction, and a support door configured to open and close an entrance of a housing, the housing having a processing space for cleaning a substrate by the brush, and the housing configured to support the brush separated from the detachable portion based on a state where the entrance is open, the detachable portion including a first paramagnetic body at one end of the brush, a second paramagnetic body at an opposite end of the brush, a first support body including a first electromagnet configured to attach and detach the first paramagnetic body by magnetic force, and a second support body including a second electromagnet configured to attach and detach the second paramagnetic body by magnetic force.

### CROSS-REFERENCE TO RELATED APPLICATION(S)

This application claims benefit of priority to Korean Patent Application No. 10-2024-0078656, filed on Jun. 18, 2024, in the Korean Intellectual Property Office, the disclosure of which is incorporated herein by reference in its entirety.

### BACKGROUND

Some example embodiments of the present disclosure relate to a brush detachable module, and a brush replacing module including the same. Furthermore, some example embodiments relate to a substrate cleaning apparatus including the brush detachable module, and more particularly to a brush detachable module capable of automatically attaching and detaching a brush, and a brush replacing module including the same.

Generally, after performing a chemical mechanical polishing (CMP) process on a wafer, a cleaning process may be performed to remove particles adhering to the wafer. The cleaning process may be mainly performed using a brush. The brush may remove particles from the wafer by physically contacting rotating brushing protrusions with the rotating wafer.

Such brushes may require replacement as they accumulate contaminants or wear out as they are used. Typically, the brushes are manually replaced, which may cause damage to the apparatus.

### SUMMARY

Some example embodiments of the present disclosure provide a brush detachable module capable of automatically attaching and detaching a brush, and a brush replacing module including the same and a substrate cleaning apparatus including the brush replacing module.

Some example embodiments of the present disclosure provide a brush detachable module capable of limiting and/or preventing damage to the apparatus during manual replacement of the brush, and a brush replacing module including the same and a substrate cleaning apparatus including the brush replacing module.

According to some example embodiments, a brush detachable module comprises a detachable portion configured to detach a brush for cleaning a substrate, a moving portion configured to move the detachable portion in an up-and-down direction, and a support door configured to open and close an entrance of a housing, the housing having a processing space for cleaning a substrate by the brush, and the housing configured to support the brush separated from the detachable portion based on a state where the entrance is open, the detachable portion including a first paramagnetic body at one end of the brush, a second paramagnetic body at an opposite end of the brush, a first support body including a first electromagnet configured to attach and detach the first paramagnetic body by magnetic force, and a second support body including a second electromagnet configured to attach and detach the second paramagnetic body by magnetic force. The moving portion is configured to move the first support body and the second support body in the same direction and at the same distance.

According to some example embodiments, a brush replacing module comprises a brush detachable module configured to replace a brush for cleaning a substrate, a brush supply recovery module configured to supply the brush to the brush detachable module and configured to recover the brush based on the brush being discharged from the brush detachable module, the brush detachable module including a detachable portion configured to detach the brush, a moving portion configured to move the detachable portion in an up-and-down direction, and a support door configured to open and close an entrance of a housing, the housing having a processing space for cleaning a substrate by the brush, and the housing configured to support the brush separated from the detachable portion based on a state where the entrance is open, the detachable portion including a first paramagnetic body at one end of the brush, a second paramagnetic body at an opposite end of the brush, a first support body including a first electromagnet configured to attach and detach the first paramagnetic body by magnetic force, and a second support body including a second electromagnet configured to attach and detach the second paramagnetic body by magnetic force. The moving portion is configured to move the first support body and the second support body in the same direction and at the same distance.

According to some example embodiments, a substrate cleaning apparatus comprises a housing having a processing space, the process space configured to be a space where cleaning of a substrate is performed, a brush configured to clean the substrate within the processing space, a brush rotation driving portion configured to rotate the brush, and a brush replacing module including a brush detachable module configured to replace the brush, the brush detachable module including a detachable portion configured to detach the brush, a moving portion configured to move the detachable portion in an up-and-down direction, and a support door configured to open and close an entrance of the housing, and the support door configured to support the brush based on the brush being separated from the detachable portion in a state where the entrance is open, the detachable portion including a first paramagnetic body at one end of the brush, a second paramagnetic body at an opposite end of the brush, a first support body including a first electromagnet configured to attach and detach the first paramagnetic body by magnetic force, and a second support body including a second electromagnet configured to attach and detach the second paramagnetic body by magnetic force. The moving portion is configured to move the first support body and the second support body in the same direction and at the same distance.

### BRIEF DESCRIPTION OF DRAWINGS

The above and other aspects, features, and advantages of some example embodiments of the present disclosure will be more clearly understood from the following detailed description, taken in conjunction with the accompanying drawings.

FIG. 1 is a horizontal cross-sectional view illustrating a substrate cleaning apparatus according to some example embodiments of the present disclosure.

FIG. 2 is a vertical cross-sectional view illustrating the inside of the housing illustrated in FIG. 1 according to the direction in which the brushes are arranged.

FIG. 3 is a side view illustration a surface of the brush illustrated in FIG. 1 facing the first support body.

FIG. 4 is a side view illustrating a surface of the first support body illustrated in FIG. 1 facing the brush.

FIG. 5 is a partial horizontal cross-sectional view illustrating a part of the brush and the first support body of FIG. 1 in a state of connected to each other cut in a horizontal direction.

FIG. 6 is a drawing illustrating the support door illustrated in FIG. 1 along the longitudinal direction of the rotation axis of the brush connected to the detachable portion.

FIG. 7 is a drawing illustrating the part where the first door body and the second door body of the support door illustrated in FIG. 1 are connected to each other from above.

FIG. 8 is a drawing illustrating the brush supply recovery module illustrated in FIG. 1 from the direction in which the housing is positioned.

FIG. 9 is a drawing illustrating the brush supply recovery module illustrated in FIG. 8 along the longitudinal direction of the rotation axis of the brush.

FIG. 10 is a drawing illustrating the surface of the first detachable body or the second detachable body illustrated in FIG. 8 facing the brush.

FIG. 11 is a schematic drawing illustrating an example of a method for detaching a brush from the detachable portion illustrated in FIG. 1.

FIG. 12 is a schematic drawing illustrating an example of a method for attaching a brush to the detachable portion illustrated in FIG. 1.

FIG. 13 is a horizontal cross-sectional view illustrating a substrate cleaning apparatus according to some example embodiments of the present disclosure.

FIG. 14 is a drawing illustrating the support door illustrated in FIG. 13 along the longitudinal direction of the rotation axis of the brush attached to the detachable portion.

FIG. 15 is a schematic drawing illustrating an example of a method for detaching a pair of brushes from the detachable portion illustrated in FIG. 13.

FIG. 16 is a schematic drawing illustrating an example of a method of attaching a brush to a detachable portion adjacent to the entrance illustrated in FIG. 13.

FIG. 17 is a schematic diagram illustrating an example of a method of attaching a brush to a detachable portion far from the entrance illustrated in FIG. 13.

FIG. 18 is a plan view illustrating a brush supply recovery module according to some example embodiments.

FIG. 19 is a drawing illustrating one side of the brush supply recovery module of FIG. 18.

FIG. 20 is a drawing illustrating a side of the transfer plate illustrated in FIG. 18 facing the direction in which the brush is attached.

### DETAILED DESCRIPTION

Hereinafter, example embodiments of the present disclosure will be clearly described in detail such that a person of ordinary skill in the art may easily implement the example embodiments.

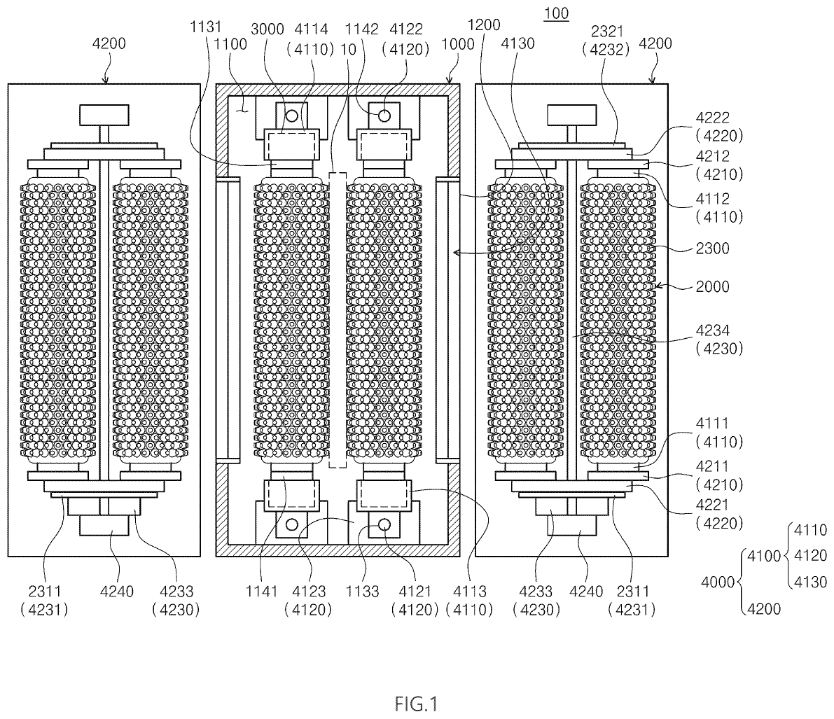

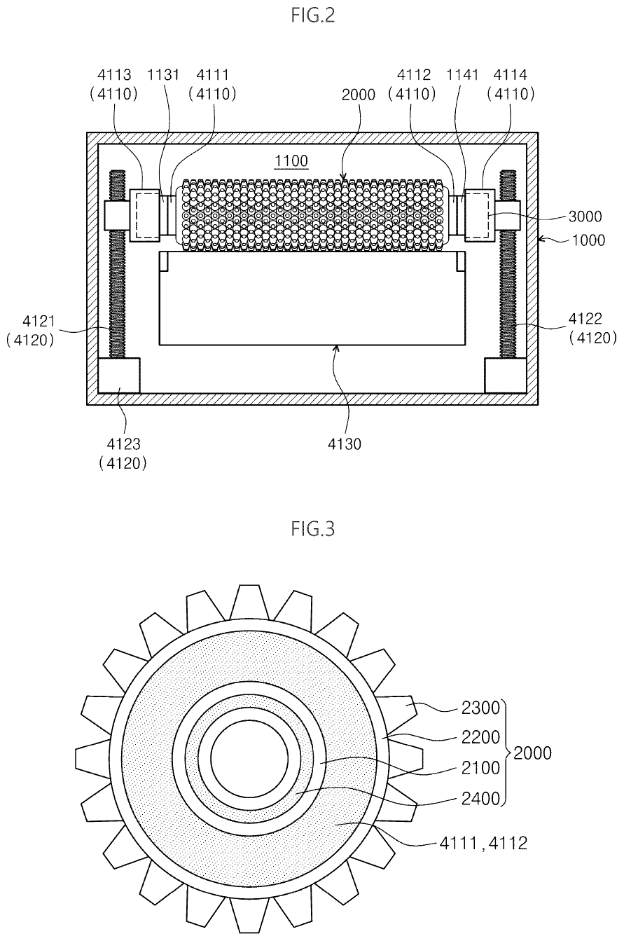

FIG. 1 is a horizontal cross-sectional view illustrating a substrate cleaning apparatus 100 according to some example embodiments of the present disclosure. FIG. 2 is a vertical cross-sectional view illustrating the inside of the housing 1000 illustrated in FIG. 1 according to the direction in which the brushes 2000 are arranged.

Referring to FIGS. 1 and 2, the substrate cleaning apparatus 100 may include a housing 1000, a brush 2000, a brush rotation driving portion 3000, and a brush replacing module 4000.

The substrate cleaning apparatus 100 may be an apparatus that cleans a substrate 10. For example, the substrate cleaning apparatus 100 may be an apparatus that performs a cleaning process to remove particles attached to the substrate 10 using a brush 2000 after performing a chemical mechanical polishing (CMP) process on the substrate 10.

The substrate 10 may be provided as a wafer or glass, etc. The substrate 10 may have a disc structure of various diameters.

The housing 1000 has a processing space 1100 therein. Cleaning of the substrate 10 is performed within the processing space 1100. An entrance 1200 may be formed on both side walls of the housing 1000 through which the processing space 1100 communicates with the outside. The brush 2000 may be moved between the inside and the outside of the processing space 1100 through the entrance 1200. The entrance 1200 may be provided at a height that does not interfere with the brush 2000 which cleans the substrate 10 when the support door 4130 is opened.

The brush 2000 cleans the substrate 10 within the processing space 1100. The brush 2000 may have brushing protrusions 2300 which physically contact both sides of the rotating substrate 10 while rotating to remove particles from the substrate 10. A pair of brushes 2000 having parallel rotation axes may be provided with the substrate 10 between them.

According to some example embodiments, the entrance 1200 may be formed on both side walls of the housing 1000 facing the direction in which the brushes 2000 are arranged. In this case, the brush rotation driving portion 3000 and the brush replacing module 4000 are provided to correspond to each brush 2000 attached within the housing. For example, a pair of brush rotation driving portions 3000, a pair of brush detachable modules 4100, and a pair of brush supply recovery modules 4200 may be provided to correspond to a pair of brushes 2000 attached within the housing 1000, respectively. In this case, the brush rotation driving portion 3000, the brush detachable module 4100 and the brush supply recovery module 4200 perform a process for an adjacent brush 2000 among the brushes 2000 attached within the housing 1000. In addition, an adjacent brush 2000 among the brushes 2000 attached within the housing 1000 enters and exits through each entrance 1200.

For convenience of explanation, only the following configurations corresponding to one brush 2000 among the pair of brushes 2000 attached within the housing 1000 will be described. The features of the configurations corresponding to the other brush 2000 among the pair of brushes 2000 attached within the housing 1000 may be identical or similar to the features of the configurations corresponding to the one brush 2000 described.

The brush rotation driving portion 3000 rotates the brush 2000 while the brushing protrusion 2300 is in contact with the substrate 10 to clean the substrate 10. According to some example embodiments, the brush rotation driving portion 3000 may include components such as an electric motor and a reducer, etc. that may provide rotational force to the brush 2000 and may control the rotational speed.

According to some example embodiments, the brush replacing module 4000 may include a brush detachable module 4100 and a brush supply recovery module 4200.

The brush detachable module 4100 may be used to replace the brush 2000. According to some example embodiments, the brush detachable module 4100 may include a detachable portion 4110, a moving portion 4120 and a support door 4130.

The brush 2000 may be detachable from the detachable portion 4110. According to some example embodiments, the detachable portion 4110 may include a first paramagnetic body 4111, a second paramagnetic body 4112, a first support body 4113, and a second support body 4114.

The first paramagnetic body 4111 may be installed at one end of the brush 2000. The second paramagnetic body 4112 may be installed at the other end of the brush 2000. The first paramagnetic body 4111 and the second paramagnetic body 4112 are provided as paramagnetic materials that may be attached to a magnet by a magnetic force. For example, the first paramagnetic body 4111 and the second paramagnetic body 4112 may be provided as a metal material including iron.

The first support body 4113 and the second support body 4114 may support the brush 2000. According to some example embodiments, the first support body 4113 and the second support body 4114 support the brush 2000 so that one end and the other end of the brush 2000 may be positioned at the same height.

The first support body 4113 includes a first electromagnet 1131. The first electromagnet 1131 may generate a magnetic force depending on whether power is applied thereto. The first electromagnet 1131 may attach and detach the first paramagnetic body 4111 depending on whether a magnetic force is generated.

The second support body 4114 includes a second electromagnet 1141. The second electromagnet 1141 may generate a magnetic force depending on whether power is applied thereto. The second electromagnet 1141 may attach and detach the second paramagnetic body 4112 depending on whether a magnetic force is generated.

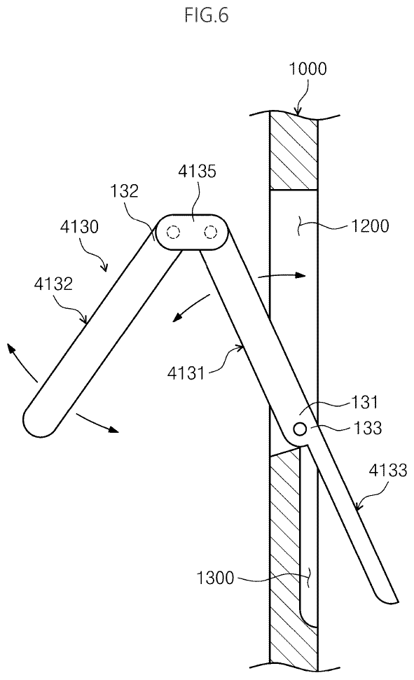

The moving portion 4120 may move the detachable portion 4110 in the up and down direction. According to some example embodiments, the moving portion 4120 moves the first support body 4113 and the second support body 4114 in the same direction and distance from each other so that when the brush 2000 is to clean the substrate 10, the brush 2000 is positioned at a cleaning position in which the rotational axis direction is parallel to the opposite brush 2000, and when the brush 2000 is to be placed on the support door 4130, the rotational axis of the brush 2000 is parallel to the upper surfaces of the first door body 4131 of FIG. 6 and the second door body 4132 of FIG. 6 of the support door 4130.

According to some example embodiments, the moving portion 4120 may include a first support shaft 4121, a second support shaft 4122 and a rotational actuator 4123. The first support shaft 4121, the second support shaft 4122 and the rotational actuator 4123 may be provided as a ball screw motor structure.

For example, the first support shaft 4121 supports the first support body 4113 to be movable along the longitudinal direction of the first support body 4113. The second support shaft 4122 supports the second support body 4114 to be movable along the longitudinal direction of the second support body 4114. A screw surface may be formed on the outer circumference surface of each of the first support shaft 4121 and the second support shaft 4122.

The rotational actuator 4123 may rotate the first support shaft 4121 with the longitudinal direction of the first support shaft 4121 as the axial direction. The rotational actuator 4123 may rotate the second support shaft 4122 with the longitudinal direction of the second support shaft 4122 as the axial direction. The rotational actuator 4123 may include components (e.g., an electric motor and a reducer, etc.) that may provide a rotational force to each of the first and second support shafts 4121, 4122 and control the rotational speed of each of the first and second support shafts 4121, 4122. Alternatively, the rotational actuator 4123 may include a single electric motor and a power connection component such as a gear, chain or belt that transmit the power of the electric motor to the first support shaft 4121 and the second support shaft 4122.

A first support shaft penetration hole 1133 may be formed in the first support body 4113. A second support shaft penetration hole 1142 may be formed in the second support body 4114. The first support shaft penetration hole 1133 penetrates the first support body 4113 in the vertical direction so that the first support shaft 4121 is engaged therewith. The second support shaft penetration hole 1142 penetrates the second support body 4114 in the vertical direction so that the second support shaft 4122 is engaged therewith. A screw surface engaged with a screw surface of an outer circumference surface of the first support shaft 4121 may be formed on the inner circumference surface of the first support shaft penetration hole 1133. A screw surface engaged with a screw surface of an outer circumference surface of the second support shaft 4122 may be formed on the inner circumference surface of the second support shaft penetration hole 1142.

According to some example embodiments, the first support shaft 4121 and the second support shaft 4122 may have same outer diameter as each other. And, the screw faces formed on the outer circumference surfaces of the first support shaft 4121 and the second support shaft 4122 may have the same specifications. In this case, the rotational actuator 4123 may rotate the first support shaft 4121 and the second support shaft 4122 at the same rotation speed.

Alternatively, the rotational actuator 4123 may be provided to rotate only one of the first support shaft 4121 and the second support shaft 4122. According to some example embodiments, the rotational actuator 4123 may be provided to rotate only the first support shaft 4121. In this case, the second support shaft 4122 and the second support body 4114 may be provided with a structure in which the second support body 4114 may move up and down along the longitudinal direction of the second support shaft 4122 according to the driving force of the rotational actuator 4123 provided to the first support shaft 4121. For example, the second support shaft 4122 may be provided with a rail structure in which the second support body 4114 is engaged therewith and moves up and down along the longitudinal direction of the second support shaft 4122.

The support door 4130 may open and close the entrance 1200 of the housing 1000. The support door 4130 may support the brush 2000 separated from the detachable portion 4110 while the entrance 1200 is open. According to some example embodiments, the support door 4130 may include a first door body 4131, a second door body 4132, and a third door body 4133.

The brush supply recovery module 4200 may supply a brush 2000 to the brush detachable module 4100 and may recover a brush 2000 discharged from the brush detachable module 4100. According to some example embodiments, the brush supply recovery module 4200 may include a supply recovery detachable portion 4210, a transfer belt 4220, a belt rotation drive portion 4230 and a support frame 4240. When a plurality of entrances 1200 are provided in the housing 1000, the brush supply recovery module 4200 may be provided at each of the positions corresponding to the entrances 1200. In this case, each brush supply recovery module 4200 may recover a brush 2000 separated from an adjacent detachable portion 4110 and supply a brush 2000 to be attached to an adjacent detachable portion 4110 into the interior of the housing 1000.

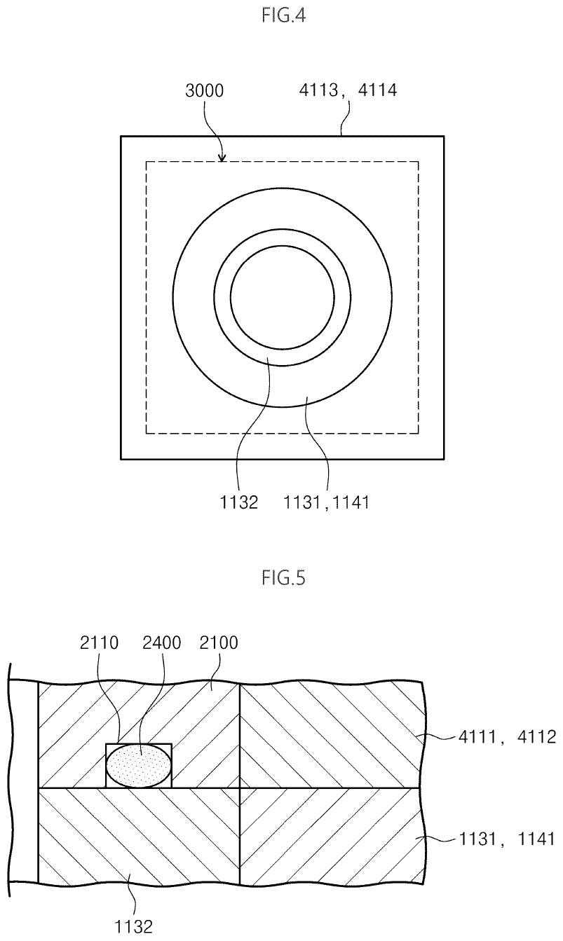

FIG. 3 is a side view illustration a surface of the brush 2000 illustrated in FIG. 1 facing the first support body 4113. FIG. 4 is a side view illustrating a surface of the first support body 4113 illustrated in FIG. 1 facing the brush 2000. FIG. 5 is a partial horizontal cross-sectional view illustrating a part of the brush 2000 and the first support body 4113 of FIG. 1 in a state of being connected to each other cut in a horizontal direction.

Referring to FIGS. 1 to 5, the brush 2000 may include an axial pipe 2100, a roller body 2200 and brushing protrusions 2300.

The axial pipe 2100 may be provided as a pipe structure having an empty interior. A chemical for processing a substrate 10 may be supplied inside the axial pipe 2100. The chemical may be a cleaning liquid for cleaning the substrate 10. The chemical may be supplied from the outside of the housing 1000 through a hose connector, which may be rotatable in the longitudinal direction as the axial direction thereof, and through a flexible hose.

The roller body 2200 may be provided as a pipe structure that surrounds the outer circumference surface of the axial pipe 2100. A chemical path may be formed by penetrating between the inner circumference surface of the axial pipe 2100 and the outer circumference surface of the roller body 2200 so that the chemical supplied into the axial pipe 2100 is discharged to the outside.

A plurality of brushing protrusions 2300 may be arranged on the outer circumference surface of the roller body 2200. Each of the brushing protrusions 2300 may be provided in a cylindrical shape. Alternatively, the brushing protrusions 2300 may be provided in various shapes as needed. And, the brushing protrusions 2300 may be provided in different sizes and/or shapes as needed. The brushing protrusions 2300 contact the substrate 10 when the brush 2000 rotates to remove particles attached to the substrate 10.

The first paramagnetic body 4111 may be provided in a ring shape that surrounds the rotational axis of the brush 2000. According to some example embodiments, the first paramagnetic body 4111 may be provided in a ring structure that surrounds the outer circumference surface of the axial pipe 2100.

The first support body 4113 may further include a connecting pipe 1132. In a state where the first paramagnetic body 4111 and the first electromagnet 1131 are connected to each other, one end of the side wall of the connecting pipe 1132 may be provided to be engaged with one end of the side wall of the axial pipe 2100 so that the chemical inside the axial pipe 2100 does not leak. One end of the connecting pipe 1132 may be provided to be open. In a case where the chemical is supplied to the axial pipe 2100 through the connecting pipe 1132, a hose or hose connector through which the chemical is supplied may be connected to the other end of the connecting pipe 1132. In contrast, in a case where the chemical is supplied to the axial pipe 2100 through another area, the other end of the connecting pipe 1132 may be provided to be closed. The lengths of the first electromagnet 1131 and the connecting pipe 1132 protruding toward the brush 2000 to which the first electromagnet 1131 and the connecting pipe 1132 are connected may be provided to be the same.

A scaling ring 2400 may be provided between the one end of the side wall of the connecting pipe 1132 and the one end of the side wall of the axial pipe 2100. The sealing ring 2400 seals so that chemicals do not leak between the connecting pipe 1132 and the axial pipe 2100. A groove 2110 in which the sealing ring 2400 is accommodated may be formed along the circumferential direction of the axial pipe 2100 on one end surface of the axial pipe 2100. The depth of the groove 2110 may be provided to be smaller than the thickness of the sealing ring 2400, so that a part of the sealing ring 2400 accommodated in the groove 2110 may protrude outside the groove 2110. The sealing ring 2400 may be provided with a material that is elastic and flexible and impermeable to fluid. For example, the sealing ring 2400 may be provided with a material such as rubber or silicone.

The first electromagnet 1131 may be provided in a ring shape that surrounds the outer circumference of the connecting pipe 1132. In a state where the first electromagnet 1131 is connected to the first paramagnetic body 4111, one end of the first electromagnet 1131 is provided to be engaged with one end of the first paramagnetic body 4111.

The first electromagnet 1131 and the connecting pipe 1132 may be rotated by the brush rotation driving portion 3000. The brush rotation driving portion 3000 may be provided within the first support body 4113. Due to the adhesion between the first electromagnet 1131 and the first paramagnetic body 4111, and the frictional force of the sealing ring 2400, the brush 2000 rotated by the brush rotation driving portion 3000 may maintain the state in which the first electromagnet 1131 and the first paramagnetic body 4111 are attached.

The brush rotation driving portion 3000 may be provided within at least one of the first support body 4113 and the second support body 4114. If the brush rotation driving portion 3000 is not provided within the first support body 4113, the first electromagnet 1131 and the connecting pipe 1132 may be provided to be rotatable around the same rotation axis as the rotation axis on which the brush 2000 rotates.

The configuration, structure, and function of the other end of the brush 2000, the second paramagnetic body 4112, and the second support body 4114, and the configuration connected thereto and connection structure thereof, etc., may be provided identically or similarly to the configuration, structure, and function of the one end of the brush 2000, the first paramagnetic body 4111 and the first support body 4113 described above.

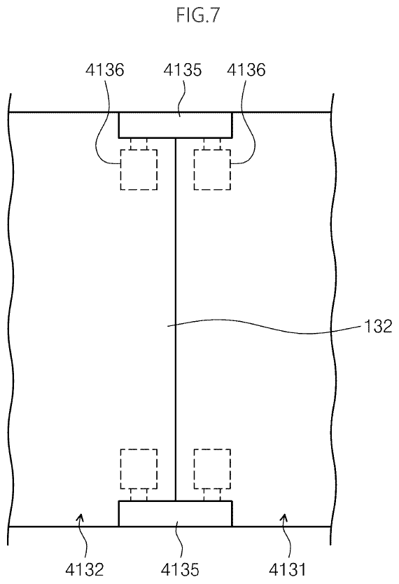

FIG. 6 is a drawing illustrating the support door 4130 illustrated in FIG. 1 along the longitudinal direction of the rotation axis of the brush 2000 connected to the detachable portion 4110. FIG. 7 is a drawing illustrating the part where the first door body 4131 and the second door body 4132 of the support door 4130 illustrated in FIG. 1 are connected to each other from above.

Referring to FIG. 6 and FIG. 7, the first door body 4131 may include a first end part 131. The first end part 131 is connected to the lower end of the entrance 1200. The first door body 4131 is provided to be rotatable with respect to the first end part 131 between a position where the entrance 1200 is closed and a position where the entrance 1200 is opened on the inside of the housing 1000. The first door body 4131 may be provided as a plate structure in which both sides thereof facing a direction perpendicular to the longitudinal direction of the rotation axis of the brush 2000. A driver may provide a driving force for the first door body 4131 to rotate with respect to the first end part 131 may be provided inside a side wall in which the entrance 1200 of the housing 1000 is formed. The driver may provide a driving force for the first door body 4131 to rotate with respect to the first end part 131 may be provided as an electric motor.

The second door body 4132 may include the second end part 132. The second end part 132 may be connected to the other end part of the first door body 4131. The second door body 4132 may be provided to be rotatable in an axial direction parallel to the rotation axis of the first door body 4131 with respect to the second end part 132 as the center of rotation. The second door body 4132 may be provided as a plate structure with both sides thereof facing a direction perpendicular to the longitudinal direction of the rotation axis of the brush 2000.

The first door body 4131 and the second door body 4132 may be connected to each other by joint portions 4135. According to some example embodiments, the joint portion 4135 connects the other end part of the first door body 4131 and the second end part 132. According to some example embodiments, the joint portions 4135 may be provided at each of the opposite side ends of the other end part of the first door body 4131 and each of the opposite side ends of the second end part 132. For example, one end of one of the joint portions 4135 is rotatably connected to one of the opposite side ends of the other end part of the first door body 4131, and the other end of the one of the joint portions 4135 is rotatably connected to one of the opposite side ends of the second end part 132. In addition, one end of the other of the joint portions 4135 is rotatably connected to the other of the opposite side ends of the other end part of the first door body 4131, and the other end of the other of the joint portions 4135 is rotatably connected to other of the opposite side ends of the second end part 132.

One end and the other end of each of the joint portions 4135 may be rotated by an electric motor 4136 provided in the first door body 4131 and an electric motor 4136 provided in the second door body 4132, respectively. By rotating one ends and the other ends of the joint portions 4135 with respect to the first door body 4131 and the second door body 4132 by the electric motors 4136, the first door body 4131 and the second door body 4132 may be rotated with respect to each other.

The third door body 4133 may include a third end part 133. The third end part 133 may be connected to the first end part 131 of FIG. 6 of the first door body 4131. When viewed along a direction parallel to the rotation axis of the first door body 4131, the third door body 4133 may be provided to be rotatable with respect to the third end part 133 in a state where the longitudinal direction of the first door body 4131 is aligned with the longitudinal direction of the third door body 4133. The third door body 4133 may be provided as a plate structure with both sides thereof facing a direction perpendicular to the longitudinal direction of the rotation axis of the brush 2000.

When viewed along the longitudinal direction of the rotation axis of the brush 2000 attached to the detachable portion 4110, when the support door 4130 closes the entrance 1200, the longitudinal directions of the first door body 4131 and the third door body 4133 are parallel to an up-down direction to block the entrance 1200. At this time, the third door body 4133 is inserted into the indentation 1300 formed in the lower area of the entrance 1200 on the outer surface of the side wall of the housing 1000. Then, the second door body 4132 is folded so that one side thereof is in close contact with one side of the first door body 4131.

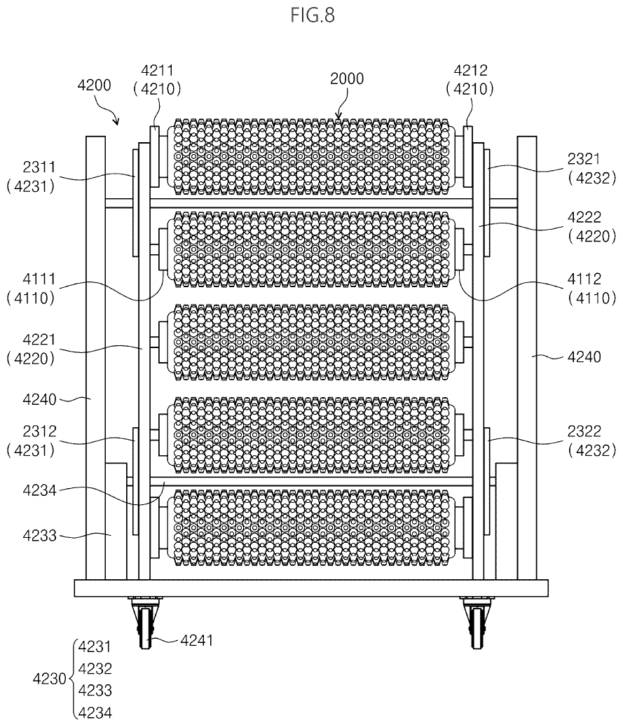

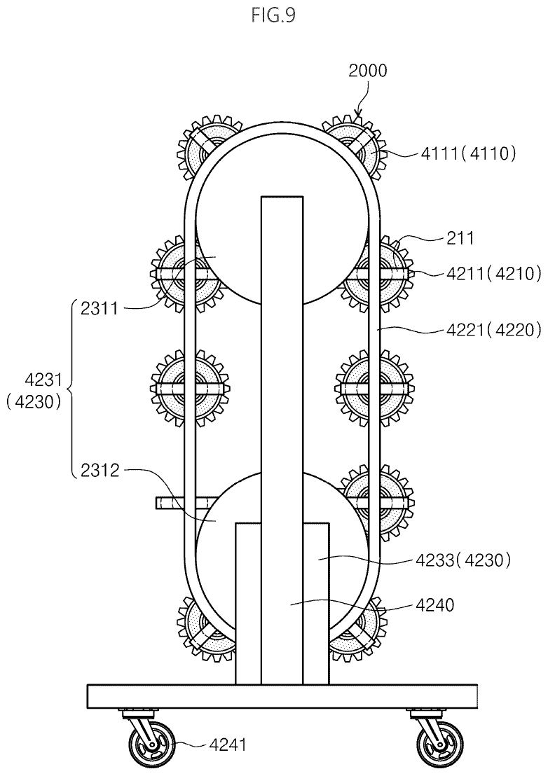

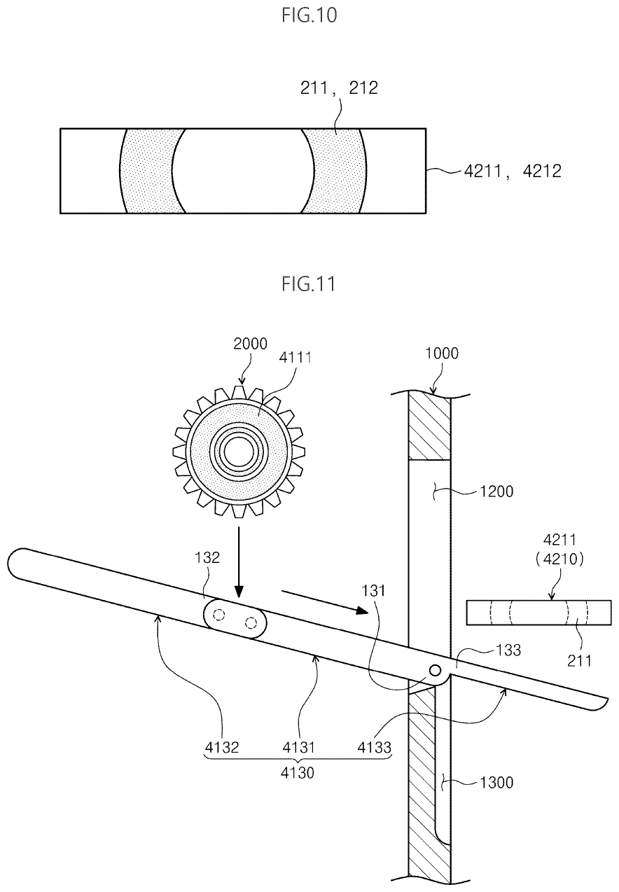

FIG. 8 is a drawing illustrating the brush supply recovery module 4200 illustrated in FIG. 1 from the direction in which the housing 1000 is positioned. FIG. 9 is a drawing illustrating the brush supply recovery module 4200 illustrated in FIG. 8 along the longitudinal direction of the rotation axis of the brush 2000. FIG. 10 is a drawing illustrating the surface of the first detachable body 4211 or the second detachable body 4212 illustrated in FIG. 8 facing the brush 2000.

Referring to FIGS. 8 to 10, a supply recovery detachable portion 4210 is provided for attaching and detaching a brush 2000. A plurality of supply recovery detachable portions 4210 may be provided, and the supply recovery detachable portions 4210 may be spaced apart from each other and connected to a transfer belt 4220 along a ring shape of the transfer belt 4220. According to some example embodiments, the supply recovery detachable portion 4210 may include a first detachable body 4211 and a second detachable body 4212.

The first detachable body 4211 may include a third electromagnet 211. The third electromagnet 211 may attach and detach a first paramagnetic body 4111 by magnetic force. According to some example embodiments, the first detachable body 4211 may be provided in a bar shape having a length direction perpendicular to the extension direction of the transfer belt 4220 and the length direction of the rotation axis of the brush 2000 attached to the third electromagnet 211. In this case, the third electromagnet 211 may be provided in an area of the first detachable body 4211 corresponding to the first paramagnetic body 4111 of the brush 2000.

The second detachable body 4212 may include the fourth electromagnet 212. The fourth electromagnet 212 may attach and detach the second paramagnetic body 4112 by magnetic force. A plurality of second detachable body 4212 may be provided, and the second detachable bodies 4212 may be respectively fastened to positions facing the first detachable bodies 4211 of the transfer belt 4220. According to some example embodiments, the second detachable body 4212 may be provided in a bar shape having a length direction perpendicular to the extension direction of the transfer belt 4220 and the length direction of the rotation axis of the brush 2000 attached to the fourth electromagnet 212. In this case, the fourth electromagnet 212 may be provided in an area of the first detachable body 4211 corresponding to the first paramagnetic body 4111 of the brush 2000.

The transfer belt 4220 may be provided in a ring shape when viewed along the longitudinal direction of the rotation axis of the brush 2000 attached to the supply recovery detachable portion 4210. According to some example embodiments, the transfer belt 4220 may include a first transfer belt 4221 and a second transfer belt 4222.

The first transfer belt 4221 and the second transfer belt 4222 are arranged to be spaced apart from each other with a position where the brush 2000 is fastened therebetween. The first transfer belt 4221 and the second transfer belt 4222 may be provided in a ring shape having the same size and shape. In addition, the first transfer belt 4221 and the second transfer belt 4222 are positioned opposite each other based on the position where the brush 2000 is fastened.

The first detachable bodies 4211 are fastened to the first transfer belt 4221. The first detachable bodies 4211 are fastened to the surface of the first transfer belt 4221 facing the position where the brush 2000 is fastened.

The second detachable bodies 4212 are fastened to the second transfer belt 4222. The second detachable bodies 4212 are fastened to the surface of the second transfer belt 4222 facing the position where the brush 2000 is fastened.

The belt rotation drive portion 4230 may rotate the transfer belt 4220 along the ring shape of the transfer belt 4220. According to some example embodiments, the belt rotation drive portion 4230 may include a first pulley 4231, a second pulley 4232, a pulley driver 4233, and a driving force transmission shaft 4234.

The first pulley 4231 may maintain the ring shape of the first transfer belt 4221 and may transmit the rotational force of the pulley driver 4233 to the first transfer belt 4221. According to some example embodiments, the first pulley 4231 may include a first upper pulley 2311 and a first lower pulley 2312. The first upper pulley 2311 and the first lower pulley 2312 are arranged in a vertical direction. The first upper pulley 2311 and the first lower pulley 2312 are positioned so that their rotation axes are parallel to each other. The first transfer belt 4221 wraps around the outer circumference of the first upper pulley 2311 and the outer circumference of the first lower pulley 2312. An additional pulley may be provided between the first upper pulley 2311 and the first lower pulley 2312 as needed depending on the size and shape of the first transfer belt 4221.

The second pulley 4232 may maintain the ring shape of the second transfer belt 4222 and may transmit the rotational power of the pulley driver 4233 to the second transfer belt 4222. According to some example embodiments, the second pulley 4232 may include the second upper pulley 2321 and the second lower pulley 2322. The second upper pulley 2321 and the second lower pulley 2322 are arranged in a vertical direction. The second upper pulley 2321 and the second lower pulley 2322 are positioned so that their rotation axes are parallel to each other. The second transfer belt 4222 wraps around the outer circumference of the second upper pulley 2321 and the outer circumference of the second lower pulley 2322. An additional pulley may be provided between the second upper pulley 2321 and the second lower pulley 2322 as needed depending on the size and shape of the second transfer belt 4222.

The pulley driver 4233 may generate a driving force to rotate the first pulley 4231 and the second pulley 4232. According to some example embodiments, the pulley driver 4233 may be directly connected to the first lower pulley 2312 to transmit the driving force. The pulley driver 4233 may be provided by an electric motor.

The driving force transmission shaft 4234 may transmit the driving force of the pulley driver 4233 connected to the first pulley 4231 to the second pulley 4232. According to some example embodiments, the driving force transmission shaft 4234 may be provided as a bar structure in which both ends thereof are respectively connected to the center of the first lower pulley 2312 and the center of the second lower pulley 2322.

The support frame 4240 supports the first pulley 4231, the second pulley 4232, and the pulley driver 4233 to maintain their relative positions with respect to each other. Each of the first pulley 4231 and the second pulley 4232 is rotatably connected to the support frame 4240. The pulley driver 4233 may be connected to a position of the support frame 4240 that the pulley driver 4233 may be connected to the first pulley 4231.

According to some example embodiments, the support frame 4240 may be provided to be horizontally movable. For example, a plurality of wheels 4241 may be provided on the bottom surface of the support frame 4240 so as to be movable by manpower. Alternatively, the support frame 4240 may include a horizontal movement driver may provide a driving force required for horizontal movement as needed.

According to some example embodiments, the substrate cleaning apparatus 100 may further include a controller that controls each component. For example, the controller may control each component of the substrate cleaning apparatus 100 to perform a method of replacing a brush 2000 attached to a detachable portion 4110 to be described below.

Some of the reducers and motors required for the operation of the substrate cleaning apparatus 100 of some example embodiments, as well as the controller described above, have been omitted from the drawings and descriptions of this specification for convenience of explanation. In addition, the power supplied to the controller, motor, and reducer, etc. may be provided by a replaceable battery, wireless charging battery, wired charging battery provided inside each component or power supplied from the outside. In addition, signals may be exchanged between the controller and the motors and reducers, etc. that require control by the controller, via wireless communication or wired communication.

FIG. 11 is a schematic drawing illustrating an example of a method for detaching a brush 2000 from the detachable portion 4110 illustrated in FIG. 1.

Referring to FIG. 11, each component of the substrate cleaning apparatus 100 may perform the following operations in order to separate the brush 2000 from the detachable portion 4110 and discharge the brush 2000 outside the housing 1000.

First, the rotation of the brush 2000 for cleaning the substrate 10 is stopped.

After this, the first door body 4131, the second door body 4132, and the third door body 4133 are rotated from the position where the entrance 1200 is closed to a position where they are inclined so that they gradually increase in height from the outside to the inside of the housing 1000. Accordingly, the entrance 1200 is opened. And, the third door body 4133 is positioned so that the other end part of the third door body 4133 protrudes toward the outside of the housing 1000.

After this, the detachable portion 4110 is lowered by the moving portion 4120 so that the brush 2000 attached to the detachable portion 4110 moves from a position at a height where the substrate 10 is cleaned to a position spaced apart from the first door body 4131 and/or the second door body 4132 by a specific height. At this time, the specific height is a height that limits and/or prevents the brush 2000, separated from the detachable portion 4110, from being damaged when it falls onto the upper surface of the first door body 4131 and/or the second door body 4132 and from being separated from the upper surface of the first door body 4131 and/or the second door body 4132, and may be set through simulation or test operation.

Next, so that the first paramagnetic body 4111 and the second paramagnetic body 4112 connected to the brush 2000 passing over the upper surface of the third door body 4133 may be attached to the third electromagnet 211 and the fourth electromagnet 212 to which the brush 2000 is not connected, respectively, the transfer belt 4220 is rotated and the support frame 4240 is moved so that the third electromagnet 211 and the fourth electromagnet 212 are positioned so that the third electromagnet 211 and the fourth electromagnet 212 may face the first paramagnetic body 4111 and the second paramagnetic body 4112 above the third door body 4133, and the power of the third electromagnet 211 and the fourth electromagnet 212 is turned on.

Thereafter, the power of the first electromagnet 1131 and the second electromagnet 1141 is turned off. Then, the brush 2000 that fell to the first door body 4131 and the second door body 4132 moves to the third door body 4133 and is attached to the supply recovery detachable portion 4210 by the first paramagnetic body 4111 and the second paramagnetic body 4112 being attached to the third electromagnet 211 and the fourth electromagnet 212.

Thereafter, the brush 2000 attached to the supply recovery detachable portion 4210 may be recovered by the brush supply recovery module 4200.

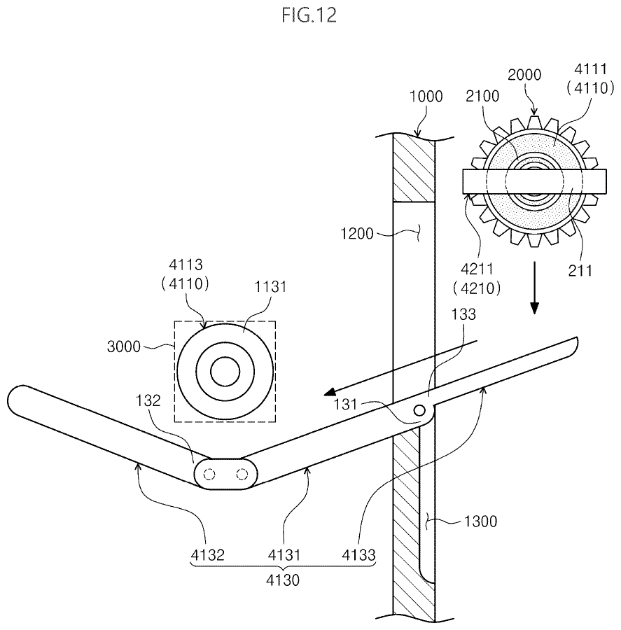

FIG. 12 is a schematic drawing illustrating an example of a method for attaching a brush 2000 to the detachable portion 4110 illustrated in FIG. 1.

Referring to FIG. 12, in order to supply the brush 2000 into the housing 1000 and attach the brush 2000 to the detachable portion 4110, each component of the substrate cleaning apparatus 100 may perform the following operations.

The first door body 4131 and the third door body 4133 are rotated to an inclined position so that they gradually increase in height from the inside to the outside of the housing 1000. In addition, the second door body 4132 is rotated to an inclined position so that they gradually increase in height from the outside to the inside of the housing 1000. Accordingly, the entrance 1200 is in an open state. In addition, the third door body 4133 is positioned so that the other end of the third door body 4133 protrudes outward from the housing 1000.

Thereafter, the transfer belt 4220 is rotated and the support frame 4240 is moved so that the supply recovery detachable portion 4210 with the brush 2000 attached is positioned at a position higher than the third door body 4133 by a specific height. At this time, the specific height is a height that limits and/or prevents the brush 2000, separated from the supply recovery detachable portion 4210, from being damaged when it falls to the upper surface of the third door body 4133 and from being separated from the upper surface of the third door body 4133, and may be set through simulation or test operation.

Next, the first support body 4113 and the second support body 4114 of the detachable portion 4110 to which the brush 2000 is not attached are moved to positions on the first door body 4131 and/or the second door body 4132 corresponding to the first paramagnetic body 4111 and the second paramagnetic body 4112 of the brush 2000 passing between the first door body 4131 and the second door body 4132, respectively, so that the first electromagnet 1131 and the second electromagnet 1141 can attach the first paramagnetic body 4111 and the second paramagnetic body 4112 of the brush 2000 passing between the first door body 4131 and the second door body 4132, respectively, and the power of the first electromagnet 1131 and the second electromagnet 1141 is turned on.

Thereafter, the power of the third electromagnet 211 and the fourth electromagnet 212 is turned off. Then, the brush 2000 that fell to the third door body 4133 moves onto the first door body 4131 and the second door body 4132, and the first paramagnetic body 4111 and the second paramagnetic body 4112 are attached to the first electromagnet 1131 and the second electromagnet 1141, thereby being fastened to the detachable portion 4110. At this time, since the inclination direction of the second door body 4132 is provided opposite to the inclination direction of the first door body 4131, the fallen brush 2000 may be caught on the second door body 4132 and may not come off the support door 4130.

Thereafter, the detachable portion 4110 may be raised by the moving portion 4120 so that the brush 2000 is positioned at the position where the substrate 10 is cleaned.

Then, the support door 4130 may be rotated so that the second door body 4132 folds on the first door body 4131, and the first door body 4131 and the third door body 4133 may be rotated to a position where the entrance 1200 is closed.

Thereafter, the brush 2000 attached to the detachable portion 4110 is rotated by the brush rotation driving portion 3000, thereby performing cleaning on the substrate 10.

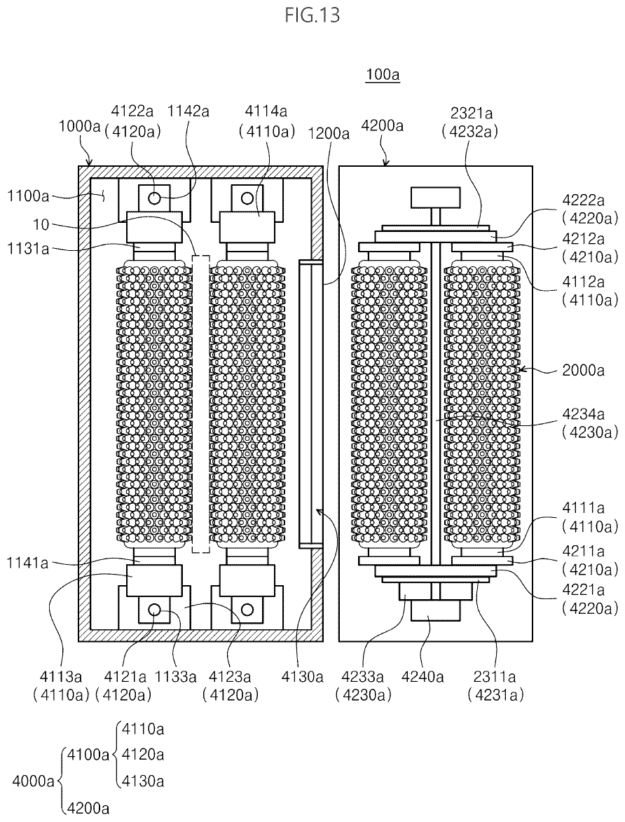

FIG. 13 is a horizontal cross-sectional view illustrating a substrate cleaning apparatus 100a according to some example embodiments of the present disclosure.

Referring to FIG. 13, unlike the substrate cleaning apparatus 100 of FIG. 1, the substrate cleaning apparatus 100a according to some example embodiments of the present disclosure is provided with a single entrance 1200a of the housing 1000a. In addition, the support door 4130a and the brush supply recovery module 4200a are provided in a single number corresponding to the entrance 1200a of the substrate cleaning apparatus 100a. At this time, the entrance 1200a is formed on one of the two side walls facing the direction in which the brushes 2000a are arranged. The brush supply recovery module 4200a is provided at a position corresponding to the entrance 1200a.

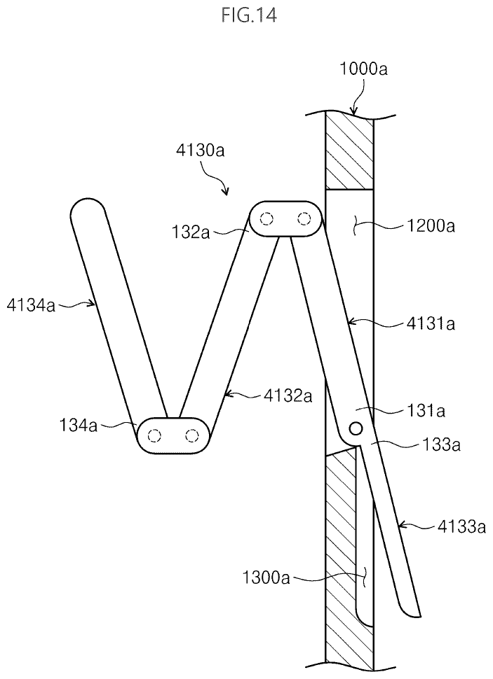

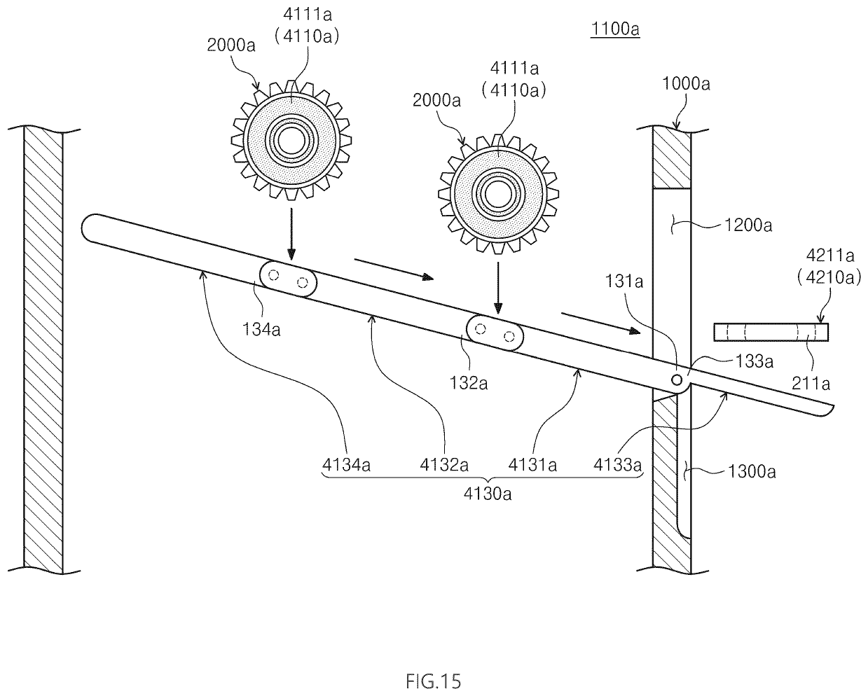

FIG. 14 is a drawing illustrating the support door 4130a illustrated in FIG. 13 along the longitudinal direction of the rotation axis of the brush 2000a attached to the detachable portion 4110a.

Referring to FIG. 14, the support door 4130a may further include a fourth door body 4134a. The fourth door body 4134a may include a fourth end part 134a. The fourth end part 134a may be connected to the other end part of the second door body 4132a. The fourth door body 4134a is provided to be rotatable in an axial direction parallel to the rotation axis of the first door body 4131a with the fourth end part 134a as the center of rotation. The connection structure and driving method between the second door body 4132a and the fourth door body 4134a may be provided identically or similarly to the connection structure and driving method between the first door body 4131 and the second door body 4132 of the above-described FIG. 1.

The features such as the configuration, structure, and function of the first door body 4131a, the second door body 4132a, and the third door body 4133a of the support door 4130a illustrated in FIG. 14 may be provided identically or similarly to the features such as the configuration, structure, and function of the first door body 4131, the second door body 4132, and the third door body 4133 of the support door 4130 of the above-described FIG. 1.

In addition, other features such as the configuration, structure, and function of the substrate cleaning apparatus 100a of FIG. 13 may be provided identically or similarly to the substrate cleaning apparatus 100 of FIG. 1.

FIG. 15 is a schematic drawing illustrating an example of a method for detaching a pair of brushes 2000a from the detachable portion 4110a illustrated in FIG. 13.

Referring to FIG. 15, each component of the substrate cleaning apparatus 100a may perform the following operations in order to separate a pair of brushes 2000a or one of a pair of brushes 2000a from the detachable portion 4110a and discharge them outside the housing 1000a.

First, the rotation of the brushes 2000a for cleaning the substrate 10 is stopped.

Thereafter, the first door body 4131a, the second door body 4132a, the third door body 4133a and the fourth door body 4134a are rotated from a position where the entrance 1200a is closed to a position where they are inclined so that they gradually increase in height from the outside to the inside of the housing 1000a. Accordingly, the entrance 1200a is opened. And, the third door body 4133a is positioned so that the other end part of the third door body 4133a protrudes to the outside of the housing 1000a. In contrast, when the brush 2000a adjacent to the entrance 1200a among the pair of brushes 2000a is discharged to the outside of the housing 1000a, the fourth door body 4134a may be maintained in a folded state with the second door body 4132a.

In the case of discharging both pairs of brushes 2000a, the subsequent operations are performed for one brush 2000a and then for the other brush 2000a. In contrast, in the case of discharging only one of the brushes 2000a, the subsequent operations are performed only for the corresponding brush 2000a.

Thereafter, the detachable portion 4110a is lowered by the moving portion 4120a so that the discharging target brush 2000a attached to the detachable portion 4110a is moved from a position at a height at which the substrate 10 is cleaned to a position spaced apart from the first door body 4131a and/or the second door body 4132a by a specific height. At this time, the specific height is a height that limits and/or prevents the brush 2000a, separated from the detachable portion 4110a, from being damaged when it falls onto the upper surface of the first door body 4131a and/or the second door body 4132a and from being separated from the upper surface of the first door body 4131a and/or the second door body 4132a, and may be set through simulation or test operation.

Then, the transfer belt 4220a is rotated and the support frame 4240a is moved so that the third electromagnet 211a and the fourth electromagnet 212a are positioned at positions where they may face the first paramagnetic body 4111a and the second paramagnetic body 4112a above the third door body 4133a so that the first paramagnetic body 4111a and the second paramagnetic body 4112a attached to the brush 2000a passing over the upper surface of the third door body 4133a may be respectively attached to the third electromagnet 211a and the fourth electromagnet 212a to which the brush 2000a is not attached. Then, the power of the third electromagnet 211a and the fourth electromagnet 212a is turned on.

Thereafter, the power of the first electromagnet 1131a and the second electromagnet 1141a is turned off. Then, the brush 2000a that fell to the first door body 4131a and the second door body 4132a moves onto the third door body 4133a, and the first paramagnetic body 4111a and the second paramagnetic body 4112a are attached to the third electromagnet 211a and the fourth electromagnet 212a, thereby being connected to the supply recovery detachable portion 4210a.

Thereafter, the brush 2000a connected to the supply recovery detachable portion 4210a may be recovered by the brush supply recovery module 4200a.

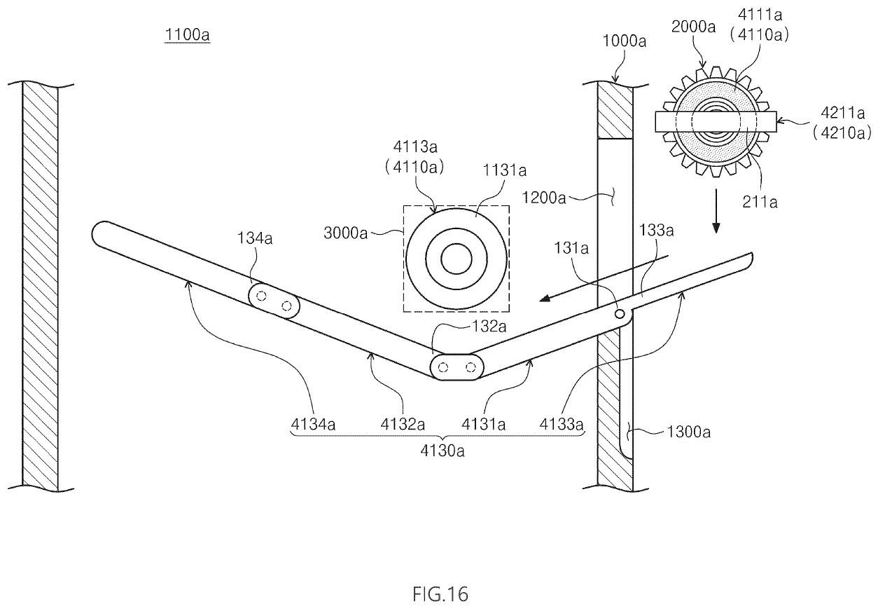

FIG. 16 is a schematic drawing illustrating an example of a method of attaching a brush 2000a to a detachable portion 4110a adjacent to the entrance 1200a illustrated in FIG. 13.

Referring to FIG. 16, each component of the substrate cleaning apparatus 100a may perform the following operations in order to supply the brush 2000a into the housing 1000a and attach the brush 2000a to the detachable portion 4110a adjacent to the entrance 1200a.

The first door body 4131a and the third door body 4133a are rotated to an inclined position that gradually increases from the inside to the outside of the housing 1000a. In addition, the second door body 4132a and the fourth door body 4134a are rotated to an inclined position that gradually increases from the outside to the inside of the housing 1000a. Accordingly, the entrance 1200a is opened. And, the third door body 4133a is positioned so that the other end part of the third door body 4133a protrudes outward from the housing 1000a. In contrast, the fourth door body 4134a may be maintained in a folded state with the second door body 4132a.

Thereafter, the transfer belt 4220a is rotated and the support frame 4240a is moved so that the supply recovery detachable portion 4210a to which the brush 2000a attached is positioned at a position that is higher than the third door body 4133a by a specific height. At this time, the specific height is a height that limits and/or prevents the brush 2000a, separated from the supply recovery detachable portion 4210a, from being damaged when it falls to the upper surface of the third door body 4133a, and from being separated from the upper surface of the third door body 4133a, and may be set through simulation or test operation.

Next, so that the first electromagnet 1131a and the second electromagnet 1141a may attach the first paramagnetic body 4111a and the second paramagnetic body 4112a of the brush 2000a passing between the first door body 4131a and the second door body 4132a, respectively, the first support body 4113a and the second support body 4114a of the detachable portion 4110a to which the brush 2000a is not attached are moved to a position on the first door body 4131a and the second door body 4132a respectively corresponding to the first paramagnetic body 4111a and the second paramagnetic body 4112a of the brush 2000a passing between the first door body 4131a and the second door body 4132a. Then, the power of the first electromagnet 1131a and the second electromagnet 1141a is turned on.

Thereafter, the power of the third electromagnet 211a and the fourth electromagnet 212a is turned off. Then, the brush 2000a that has fallen onto the third door body 4133a moves onto the first door body 4131a and the second door body 4132a, and the first paramagnetic body 4111a and the second paramagnetic body 4112a are attached to the first electromagnet 1131a and the second electromagnet 1141a, thereby being fastened to the detachable portion 4110a. At this time, since the inclination direction of the second door body 4132a and/or the fourth door body 4134a is provided opposite to the inclination direction of the first door body 4131a, the fallen brush 2000a may be caught on the second door body 4132a and/or the fourth door body 4134a and may not come off the support door 4130a.

Thereafter, the detachable portion 4110a may be raised by the moving portion 4120a so that the brush 2000a is positioned at the position where the substrate 10 is cleaned.

Next, the support door 4130a may rotate to fold the fourth door body 4134a onto the second door body 4132a, rotate to fold the second door body 4132a onto the first door body 4131a, and rotate to a position where the first door body 4131a and the third door body 4133a close the entrance 1200a.

Thereafter, the brush 2000a attached to the detachable portion 4110a is rotated by the brush rotation driving portion 3000a, thereby performing cleaning on the substrate 10.

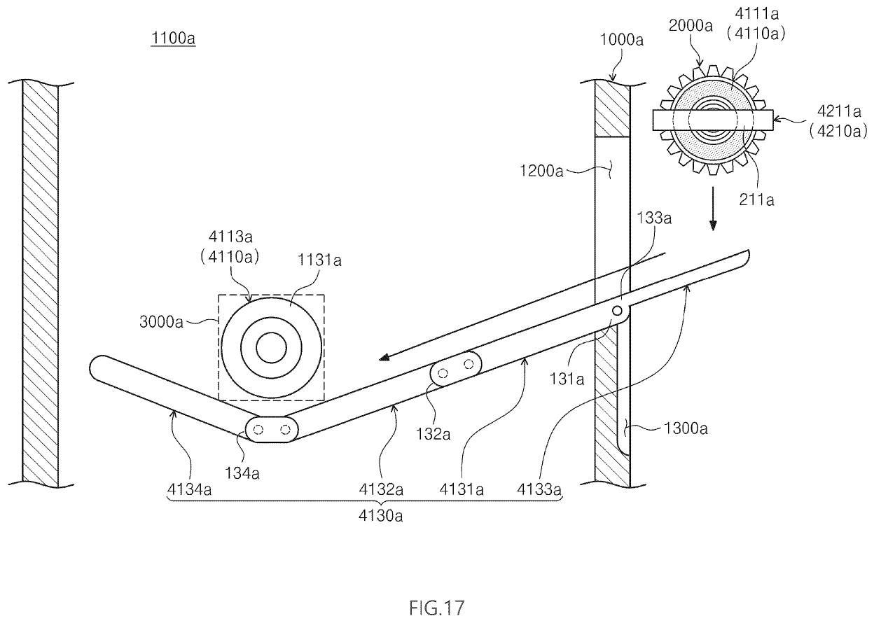

FIG. 17 is a schematic diagram illustrating an example of a method of attaching a brush 2000a to a detachable portion 4110a far from the entrance 1200a illustrated in FIG. 13.

Referring to FIG. 17, in order to supply the brush 2000a into the housing 1000a and attach the brush 2000a to the detachable portion 4110a far from the entrance 1200a, each component of the substrate cleaning apparatus 100a may perform the following operations.

The first door body 4131a, the second door body 4132a and the third door body 4133a are rotated to an inclined position so that they gradually increase in height from the inside to the outside of the housing 1000a. In addition, the fourth door body 4134a is rotated to an inclined position so that the fourth door body 4134a gradually increase in height from the outside to the inside of the housing 1000a. Accordingly, the entrance 1200a is in an open state. In addition, the third door body 4133a is positioned so that other end part thereof protrudes outward from the housing 1000a.

Thereafter, the transfer belt 4220a is rotated and the support frame 4240a is moved so that the supply recovery detachable portion 4210a to which the brush 2000a attached is positioned at a specific height higher than the third door body 4133a. At this time, the specific height is a height that limits and/or prevents the brush 2000a, separated from the supply recovery detachable portion 4210a, from being damaged when the brush 2000a falls to the upper surface of the third door body 4133a and from being separated from the upper surface of the third door body 4133a, and may be set through simulation or test operation.

Next, so that the first electromagnet 1131a and the second electromagnet 1141a may attach the first paramagnetic body 4111a and the second paramagnetic body 4112a of the brush 2000a passing between the second door body 4132a and the fourth door body 4134a, respectively, the first support body 4113a and the second support body 4114a of the detachable portion 4110a to which the brush 2000a is not attached are moved to a position on the second door body 4132a and the fourth door body 4134a respectively corresponding to the first paramagnetic body 4111a and the second paramagnetic body 4112a of the brush 2000a passing between the second door body 4132a and the fourth door body 4134a. Then, the power of the first electromagnet 1131a and the second electromagnet 1141a is turned on.

Thereafter, the power of the third electromagnet 211a and the fourth electromagnet 212a is turned off. Then the brush 2000a that fell to the third door body 4133a moves onto the first door body 4131a, the second door body 4132a and the fourth door body 4134a, and the first paramagnetic body 4111a and the second paramagnetic body 4112a are attached to the first electromagnet 1131a and the second electromagnet 1141a, thereby being attached to the detachable portion 4110a. At this time, since the inclination direction of the fourth door body 4134a is provided opposite to the inclination direction of the first door body 4131a, the fallen brush 2000a is caught on the fourth door body 4134a and may not come off the support door 4130a.

Thereafter, the detachable portion 4110a may be raised by the moving portion 4120a so that the brush 2000a is positioned at the position where the substrate 10 is cleaned.

Next, the support door 4130a may rotate to fold the fourth door body 4134a onto the second door body 4132a, rotate to fold the second door body 4132a onto the first door body 4131a, and rotate to a position where the first door body 4131a and the third door body 4133a close the entrance 1200a.

Thereafter, the brush 2000a attached to the detachable portion 4110a is rotated by the brush rotation driving portion 3000a, thereby performing cleaning on the substrate 10.

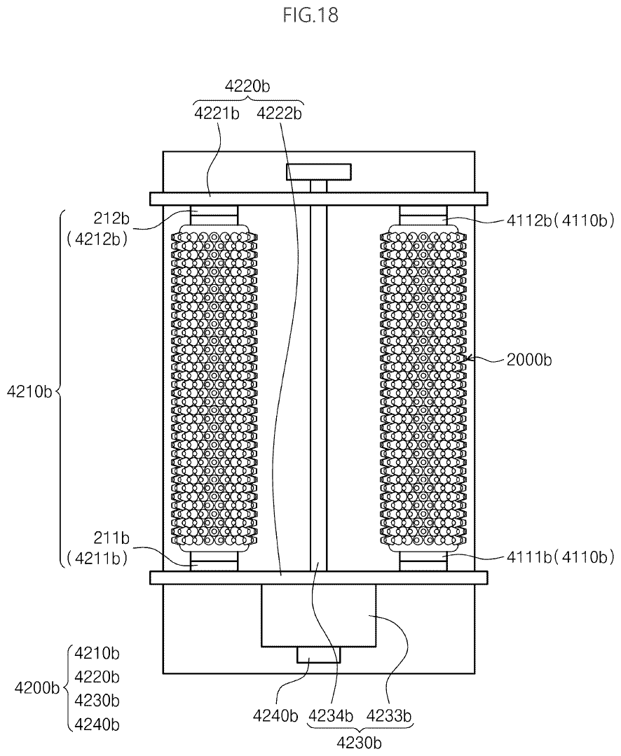

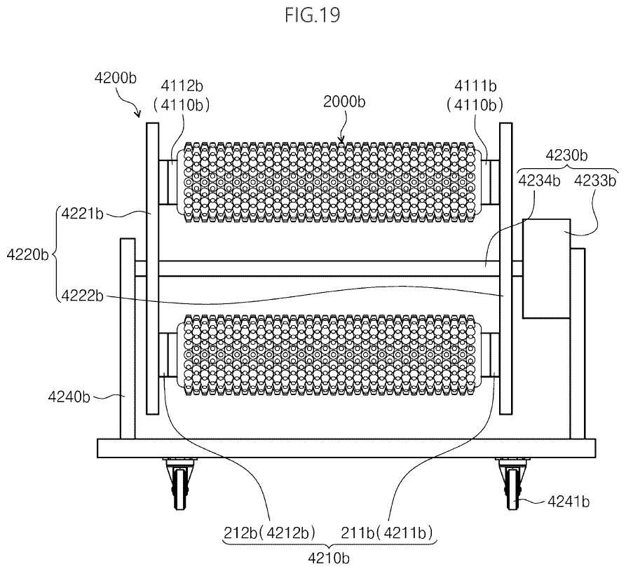

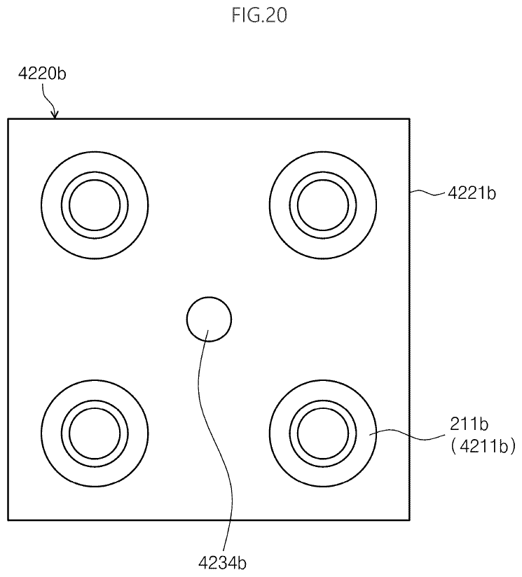

FIG. 18 is a plan view illustrating a brush supply recovery module 4200b according to some example embodiments. FIG. 19 is a drawing illustrating one side of the brush supply recovery module 4200b of FIG. 18. FIG. 20 is a drawing illustrating a side of the transfer plate 4220b illustrated in FIG. 18 facing the direction in which the brush 2000b is attached.

Referring to FIGS. 18 to 20, the brush supply recovery module 4200b may include a supply recovery detachable portion 4210b, a transfer plate 4220b, a plate rotation drive portion 4230b, and a support frame 4240b.

The supply recovery detachable portion 4210b is provided for the brush 2000b to be attached and detached. When viewed along the longitudinal direction of the rotation axis of the brush 2000b attached to the brush supply recovery module 4200b, a plurality of supply recovery detachable portions 4210b may be provided, and the supply recovery detachable portions 4210b may be fastened to the transfer plate 4220b spaced apart from each other along a ring shape.

According to some example embodiments, the supply recovery detachable portion 4210b may include a first detachable body 4211b and a second detachable body 4212b.

The first detachable body 4211b may include a third electromagnet 211b. The third electromagnet 211b may attach and detach the first paramagnetic body 4111b by magnetic force. According to some example embodiments, when looking at the brush 2000b attached to the first detachable body 4211b, the third electromagnet 211b may be provided in a ring shape corresponding to the first paramagnetic body 4111b.

The second detachable body 4212b may include a fourth electromagnet 212b. The fourth electromagnet 212b may attach and detach the second paramagnetic body 4112b by magnetic force. A plurality of the second detachable body 4212b may be provided, and the second detachable bodies 4212b may be respectively fastened to positions of the transfer plate 4220b facing the first detachable bodies 4211b. According to some example embodiments, when looking at the brush 2000b attached to the second detachable body 4212b, the fourth electromagnet 212b may be provided in a ring shape corresponding to the second paramagnetic body 4112b.

The transfer plate 4220b may be provided in a plate shape positioned so that both sides thereof are facing along the longitudinal direction of the rotational axis of the brush 2000b attached to the supply recovery detachable portion 4210b. According to some example embodiments, the transfer plate 4220b may include a first transfer plate 4221b and a second transfer plate 4222b.

One side of the first transfer plate 4221b and one side of the second transfer plate 4222b may be arranged to face each other with the position where the brush 2000b is fastened therebetween. The first transfer plate 4221b and the second transfer plate 4222b may have plate shapes having the same size and shape.

The first detachable bodies 4211b may be fastened to the first transfer plate 4221b. The first detachable bodies 4211b may be fastened and arranged in a ring shape to the one side of the first transfer plate 4221b facing the position where the brush 2000b is fastened.

The second detachable bodies 4212b may be fastened to the second transfer plate 4222b. The second detachable bodies 4212b may fastened and arranged in a ring shape on the one side of the second transfer plate 4222b facing the position where the brush 2000b is attached.

The plate rotation drive portion 4230b may rotate the transfer plate 4220b along the ring shape in which the first detachable bodies 4211b and the second detachable bodies 4212b are arranged. According to some example embodiments, the plate rotation drive portion 4230b may include a plate driver 4233b and a driving force transmission shaft 4234b.

The plate driver 4233b may generate a driving force for rotating the first transfer plate 4221b and the second transfer plate 4222b. According to some example embodiments, the plate driver 4233b may be directly connected to the first transfer plate 4221b and transmit the driving force. The plate driver 4233b may be provided as an electric motor.

The driving force transmission shaft 4234b may transmit the driving force of the plate driver 4233b connected to the first transfer plate 4221b to the second transfer plate 4222b.

According to some example embodiments, the driving force transmission shaft 4234b may be provided as a bar structure in which both ends thereof are respectively connected to the rotation center of the first transfer plate 4221b and the rotation center of the second transfer plate 4222b.

The support frame 4240b may support the transfer plate 4220b and the plate driver 4233b to maintain their relative positions with respect to each other. The first transfer plate 4221b and the second transfer plate 4222b are each rotatably fastened to the support frame 4240b. The plate driver 4233b may be fastened to a position of the support frame 4240b that may be connected to the first transfer plate 4221b.

Other features of the brush 2000b and the brush supply recovery module 4200b, such as configuration, structure, function, and operation method, etc. thereof, may be provided identically or similarly to the brush supply recovery module 4200, 4200a illustrated in FIGS. 1 and 13.

The brush detachable module, and the brush replacing module including the same, and substrate cleaning apparatus including the brush detachable module according to example embodiments of some example embodiments may automatically attach and detach the brush by having the configurations including the electromagnets as described above. Therefore, the brush detachable module, and the brush replacing module, and substrate cleaning apparatus including the brush detachable module according to some example embodiments of the present disclosure may limit and/or prevent damage to the apparatus due to manual replacement of the brush.

While the present disclosure has been described with reference to some example embodiments thereof, it will be apparent to those of ordinary skill in the art that various changes and modifications may be made thereto without departing from the spirit and scope of the present disclosure as set forth in the following claims.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A brush detachable module comprising:
a detachable portion configured to detach a brush for cleaning a substrate;
a moving portion configured to move the detachable portion in an up-and-down direction; and
a support door configured to open and close an entrance of a housing, the housing having a processing space for cleaning a substrate by the brush, and the support door configured to support the brush separated from the detachable portion based on a state where the entrance is open;
the detachable portion including
a first paramagnetic body at one end of the brush,
a second paramagnetic body at an opposite end of the brush,
a first support body including a first electromagnet configured to attach and detach the first paramagnetic body by magnetic force, and
a second support body including a second electromagnet configured to attach and detach the second paramagnetic body by magnetic force,
wherein the moving portion is configured to move the first support body and the second support body in the same direction and at the same distance.

2. The brush detachable module of claim 1, wherein
the moving portion includes:
a first support shaft configured to support the first support body;
a second support shaft configured to support the second support body; and
a rotational actuator configured to rotate the first support shaft with the longitudinal direction of the first support shaft as the axial direction,
wherein the first support body is configured to be movable along the longitudinal direction of the first support shaft,
the second support body is configured to be movable along the longitudinal direction of the second support shaft,
a support shaft penetration hole is in the first support body through which the first support shaft is configured to be engaged and penetrating,
an outer screw surface is on an outer circumference surface of the first support shaft, and
an inner screw surface is on an inner circumference surface of the support shaft penetration hole that is configured to engage with the outer screw surface of the outer circumference surface of the first support shaft.

3. The brush detachable module of claim 1, wherein
the support door includes:
a first door body including a first end part configured to be connected to the lower end of the entrance, and
the first door body configured to rotate between a position where the entrance is closed and a position inside the housing where the entrance is opened, with respect to the first end part as the center of rotation; and
a second door body including a second end part configured to be connected to an opposite end part of the first door body, and
the second door body configured to rotate in an axial direction parallel to the rotational axis of the first door body, with respect to the second end part as the center of rotation.

4. The brush detachable module of claim 3, wherein
the support door further includes:
a third door body including a third end part connected to the first end part of the first door body, and
the third door body configured to rotate in a state where a longitudinal direction thereof is aligned with the first door body with respect to the third end part as the center of rotation when viewed along a direction parallel to the rotational axis of the first door body.

5. The brush detachable module of claim 3, wherein
the support door includes
a fourth door body including a third end part connected to an opposite end part of the second door body, and
the fourth door body configured to rotate in an axial direction parallel to the rotation axis of the first door body with respect to the third end part as the center of rotation.

6. The brush detachable module of claim 4, wherein
the first door body and the third door body are configured to be positioned at an inclined position so as to become higher from the inside to the outside of the housing, and the second door body is configured to be positioned at an inclined position so as to become higher further away from the outside of the housing, based on the brush being supported on the support door to be attached to the detachable portion, and
wherein the first door body, the second door body and the third door body are configured to be positioned together at an inclined position so as to become higher from the outside to the inside of the housing, based on the brush being detached from the detachable portion.

7. The brush detachable module of claim 5, wherein
The first door body and the second door body are configured to be positioned together at an inclined position so as to become higher from the inside to the outside of the housing, and the fourth door body is configured to be positioned at an inclined position so as to become higher further away from the outside of the housing, based on the brush being supported on the support door to be attached to the detachable portion, and
the first door body, the second door body, and the fourth door body are configured to be positioned together at an inclined position so as to become higher from the outside to the inside of the housing, based on the brush being separated from the detachable portion,

8. The brush detachable module of claim 1, wherein
the first paramagnetic body and the second paramagnetic body are provided in ring shapes that surround the rotational axis of the brush.

9. A brush replacing module comprising:
a brush detachable module configured to replace a brush for cleaning a substrate;
a brush supply recovery module configured to supply the brush to the brush detachable module and configured to recover the brush based on the brush being discharged from the brush detachable module;
the brush detachable module including
a detachable portion configured to detach the brush,
a moving portion configured to move the detachable portion in an up-and-down direction, and
a support door configured to open and close an entrance of a housing, the housing having a processing space for cleaning a substrate by the brush, and the support door configured to support the brush separated from the detachable portion based on a state where the entrance is open;
the detachable portion including
a first paramagnetic body at one end of the brush,
a second paramagnetic body at an opposite end of the brush,
a first support body including a first electromagnet configured to attach and detach the first paramagnetic body by magnetic force, and
a second support body including a second electromagnet configured to attach and detach the second paramagnetic body by magnetic force,
wherein the moving portion is configured to move the first support body and the second support body in the same direction and at the same distance.

10. The brush replacing module of claim 9, wherein
the moving portion includes:
a first support shaft configured to support the first support body;
a second support shaft configured to support the second support body; and
a rotational actuator configured to rotate the first support shaft with the longitudinal direction of the first support shaft as the axial direction,
wherein the first support body is configured to be movable along the longitudinal direction of the first support shaft,
the second support body is configured to be movable along the longitudinal direction of the second support shaft,
a support shaft penetration hole is in the first support body through which the first support shaft is configured to be engaged and penetrating,
an outer screw surface is on an outer circumference surface of the first support shaft, and
an inner screw surface is on an inner circumference surface of the support shaft penetration hole that is configured to engage with the outer screw surface of the outer circumference surface of the first support shaft.

11. The brush replacing module of claim 9, wherein
the brush supply recovery module comprises:
a plurality of supply recovery detachable portions arranged in a ring shape and spaced apart from each other when viewed along the longitudinal direction of the rotation axis of the brush, and configured to be detachable from the brush; and
a belt rotation drive portion configured to rotate the supply recovery detachable portions along the ring shape,
wherein each of the supply recovery detachable portions includes
a first detachable body including a third electromagnet configured to attach and detach the first paramagnetic body by magnetic force, and
a second detachable body including a fourth electromagnet configured to attach and detach the second paramagnetic body by magnetic force.

12. The brush replacing module of claim 11, wherein
the support door includes:
a first door body including a first end part configured to be connected to the lower end of the entrance, and
the first door body being configured to rotate between a position where the entrance is closed and a position inside the housing where the entrance is opened, with respect to the first end part as the center of rotation; and
a second door body including a second end part configured to be connected to an opposite end part of the first door body, and
the second door body being configured to rotate in an axial direction parallel to the rotational axis of the first door body, with respect to the second end part as the center of rotation.

13. The brush replacing module of claim 12, wherein
the support door further includes:
a third door body including a third end part connected to the first end part of the first door body, and
the third door body configured to rotate in a state where a longitudinal direction thereof is aligned with the first door body with respect to the third end part as the center of rotation when viewed along a direction parallel to the rotational axis of the first door body.

14. The brush replacing module of claim 13, wherein
the support door is configured to be positioned based on being in a state where the entrance is opened so that an opposite end part of the third door body protrudes outward from the housing, and
the brush supply recovery module is configured to be positioned such that the third electromagnet and the fourth electromagnet are on the third door body based on supplying the brush to the brush detachable module or discharging the brush from the brush detachable module.

15. A substrate cleaning apparatus comprising:
a housing having a processing space, the process space configured to be a space where cleaning of a substrate is performed;
a brush configured to clean the substrate within the processing space;
a brush rotation driving portion configured to rotate the brush; and
a brush replacing module including a brush detachable module configured to replace the brush;
the brush detachable module including
a detachable portion configured to detach the brush,
a moving portion configured to move the detachable portion in an up-and-down direction,
a support door configured to open and close an entrance of the housing, and
the support door configured to support the brush based on the brush being separated from the detachable portion in a state where the entrance is open;
the detachable portion including
a first paramagnetic body at one end of the brush,
a second paramagnetic body at an opposite end of the brush;
a first support body including a first electromagnet configured to attach and detach the first paramagnetic body by magnetic force, and
a second support body including a second electromagnet configured to attach and detach the second paramagnetic body by magnetic force,
wherein the moving portion is configured to move the first support body and the second support body in the same direction and at the same distance.

16. The substrate cleaning apparatus of claim 15, wherein
the moving portion includes:
a first support shaft configured to support the first support body;
a second support shaft configured to support the second support body; and
a rotational actuator configured to rotate the first support shaft with the longitudinal direction of the first support shaft as the axial direction,
wherein the first support body is configured to be movable along the longitudinal direction of the first support shaft,
the second support body is configured to be movable along the longitudinal direction of the second support shaft,
a support shaft penetration hole is in the first support body through which the first support shaft is configured to be engaged and penetrating,
an outer screw surface is on an outer circumference surface of the first support shaft, and
an inner screw surface is on an inner circumference surface of the support shaft penetration hole that is configured to engage with the outer screw surface of the outer circumference surface of the first support shaft.

17. The substrate cleaning apparatus of claim 15, wherein
the support door includes:
a first door body including a first end part configured to be connected to the lower end of the entrance, and
the first door body configured to rotate between a position where the entrance is closed and a position inside the housing where the entrance is opened, with respect to the first end part as the center of rotation; and
a second door body including a second end part configured to be connected to an opposite end part of the first door body, and
the second door body configured to rotate in an axial direction parallel to the rotational axis of the first door body, with respect to the second end part as the center of rotation.

18. The substrate cleaning apparatus of claim 17, wherein
the support door further includes:
a third door body including a third end part connected to the first end part of the first door body, and
the third door body configured to rotate in a state where a longitudinal direction thereof is aligned with the first door body with respect to the third end part as the center of rotation when viewed along a direction parallel to the rotational axis of the first door body.

19. The substrate cleaning apparatus of claim 15, wherein
the brush replacing module further includes:
a brush supply recovery module configured to supply the brush to the brush detachable module and configured to recover the brush based on the brush being discharged from the brush detachable module,
the brush supply recovery module including
a plurality of supply recovery detachable portions arranged in a ring shape and spaced apart from each other when viewed along the longitudinal direction of the rotation axis of the brush, and configured to be detachable from the brush, and
a belt rotation drive portion configured to rotate the supply recovery detachable portions along the ring shape,
wherein each of the supply recovery detachable portions includes
a first detachable body including a third electromagnet configured to attach and detach the first paramagnetic body by magnetic force, and
a second detachable body including a fourth electromagnet configured to attach and detach the second paramagnetic body by magnetic force.

20. The substrate cleaning apparatus of claim 19, wherein
the support door includes:
a first door body including a first end part configured to be connected to the lower end of the entrance, and
the first door body being configured to rotate between a position where the entrance is closed and a position inside the housing where the entrance is opened, with respect to the first end part as the center of rotation; and
a third door body including a third end part connected to the first end part of the first door body, and
the third door body configured to rotate in a state where a longitudinal direction thereof is aligned with the first door body with respect to the third end part as the center of rotation when viewed along a direction parallel to the rotational axis of the first door body,
wherein the support door is configured to be positioned based on being in a state where the entrance is opened so that an opposite end part of the third door body protrudes outward from the housing, and
the brush supply recovery module is configured to be positioned such that the third electromagnet and the fourth electromagnet are on the third door body based on supplying the brush to the brush detachable module or discharging the brush from the brush detachable module.
